(19) United States
(12) Patent Application Publication
(10) Pub. No.: US 2007/0069792 A1
(43) Pub. Date: Mar. 29, 2007

(54) Delay circuit

(76) Inventor: Kwang-Myoung Rho, Kyoungki-do (KR)

Correspondence Address: MCDERMOTT WILL & EMERY LLP, 600 13TH STREET, N.W., WASHINGTON, DC, 20005-3096, US

(21) Appl. No.: 11/528,636

(22) Filed: Sep. 28, 2006

(30) Foreign Application Priority Data
Sep. 29, 2005 (KR) 2005-0090881
May 15, 2006 (KR) 2006-0043561

(51) Int. Cl. H03H 11/26

(52) U.S. Cl. 327/261

(57) ABSTRACT

A delay circuit controls a delay time according to variation of a power supply voltage. In the delay circuit, the capacitance of a capacitor connected in parallel to the delay line is changed according to the change of the power supply voltage. Alternatively, a current is made to flow through one path selected from a plurality of paths having different resistance between the input and the output of the delay line. Accordingly, the delay time can be independently controlled or adjusted by greatly changing the time taken to pass through the delay line according to the change of the power supply voltage.

### FIELD OF THE INVENTION

The present invention relates to a semiconductor device, and more particularly, to a delay circuit for controlling a delay time according to variation of a power supply voltage.

### DESCRIPTION OF RELATED ART

A delay circuit is a basic circuit that is widely used to determine order of internal control signals in Dynamic Random Access Memory (DRAM) and Application-Specific Integrated Circuit (ASIC).

FIG. 1A is a circuit diagram illustrating an example of a conventional delay circuit.

The delay circuit of FIG. 1A is an inverter chain type delay circuit with a plurality of inverters and determines a delay signal only using logic delay time.

FIG. 1B is a circuit diagram illustrating another example of a conventional delay circuit.

The delay circuit of FIG. 1B is a capacitor-type delay circuit that determines a delay signal by using time taken to charge and discharge a capacitor through logic gates.

FIG. 1C is a circuit diagram illustrating a further another example of a conventional delay circuit.

The delay circuit of FIG. 1C is a resistor-capacitor (R-C) type delay circuit that determines a delay signal by using time taken to charge and discharge the capacitor through a specific output resistor.

The above-described delay circuits have their respective characteristics in terms of delay time value, delay time being dependent on a power supply voltage, and delay time variation according to process changes. Therefore, the delay circuits are properly applied according to the required characteristics.

FIG. 1D is a graph illustrating variation of a delay time when a voltage level of a power supply voltage VDD changes in the conventional delay circuits of FIGS. 1A to 1C.

Referring to FIG. 1D, the R-C type delay circuit of FIG. 3 has the smallest variation range of the delay time with respect to the change of the power supply voltag VDD, while the inverter chain type delay circuit of FIG. 1A has the greatest variation range of the delay time with respect to the change of the power supply voltage VDD.

Although the conventional delay circuits of FIGS. 1A to 1C have different variation ranges with respect to the change of the power supply voltage, they cannot independently control or adjust the delay time according to the change of the power supply voltage because the delay time changes linearly. When a voltage level of the power supply voltage is divided into a high operating voltage higher than a predetermined set voltage and a low operating voltage lower than the predetermined set voltage so as to independently control or adjust the delay time according to the change of the power supply voltage, the delay time at the high operating voltage and the delay time at the low operating voltage change linearly, so that there is no significant difference between the delay times.

### SUMMARY OF THE INVENTION

It is, therefore, an object of the present invention to provide a delay circuit that can control delay time at a high operating voltage and a low operating voltage independently and easily.

In accordance with an aspect of the present invention, there is provided a delay circuit including: a plurality of inverters, connected in series, for delaying an input signal; a power supply voltage detector for detecting whether a power supply voltage is higher or lower than a predetermined threshold voltage; and a load connected to a node between the inverters and having different impedances according to levels of the power supply voltage in response to the detected result of the power supply voltage detector.

In accordance with another aspect of the present invention, there is provided a delay circuit including: a capacitor having one terminal connected to a node of a delay line; a switching unit connected between the other terminal of the capacitor and a ground terminal; and a power supply voltage detector for controlling the switching unit by detecting whether a power supply voltage is higher or lower than a predetermined threshold voltage.

In accordance with a further aspect of the present invention, there is provided a delay circuit including: a resistor connected between an output terminal of a first inverter and an input terminal of a second inverter, the first and second inverters forming a delay line; a switching unit connected in parallel to the resistor between the output terminal of the first inverter and the input terminal of the second inverter; and a power supply voltage detector for controlling the switching unit by detecting whether a power supply voltage is higher or lower than a predetermined threshold voltage.

The delay circuit in accordance with the present invention can easily control the dependence of the delay time on the power supply voltage by rapidly varying the load capacitance or resistance according to the change of the power supply voltage.

### BRIEF DESCRIPTION OF THE DRAWINGS

The above and other objects and features of the present invention will become apparent from the following description of the preferred embodiments given in conjunction with the accompanying drawings, in which:

FIG. 1A is a circuit diagram illustrating an example of a conventional delay circuit;

FIG. 1B is a circuit diagram illustrating another example of a conventional delay circuit;

FIG. 1C is a circuit diagram illustrating further another example of a conventional delay circuit;

FIG. 1D is a graph illustrating variation of a delay time when a voltage level of a power supply voltage changes in the conventional delay circuits of FIGS. 1A to 1C;

FIG. 2A is a circuit diagram of a delay circuit in accordance with a first embodiment of the present invention;

FIG. 2B is a graph illustrating variation of a load capacitance looking into a node A when a voltage level of a power supply voltage changes in the delay circuit of FIG. 2A;

FIG. 2C is a graph illustrating variation of a delay time when a voltage level of a power supply voltage changes in the delay circuit of FIG. 1B and the delay circuit of FIG. 2A;

FIG. 3A is a circuit diagram of a delay circuit in accordance with a second embodiment of the present invention;

FIG. 3B is a graph illustrating variation of a load capacitance looking into a node A when a voltage level of a power supply voltage changes in the delay circuit of FIG. 3A;

FIG. 3C is a graph illustrating variation of a delay time when a voltage level of a power supply voltage changes in the conventional delay circuit of FIG. 1B and the delay circuit of FIG. 3A;

FIG. 4A is a circuit of a delay circuit in accordance with a third embodiment of the present invention;

FIG. 4B is a graph illustrating variation of an effective resistance between a node A and a node B when a voltage level of a power supply voltage changes in the delay circuit of FIG. 4A;

FIG. 4C is a graph illustrating variation of a delay time when a voltage level of a power supply voltage changes in the conventional delay circuit of FIG. 1C and the delay circuit of FIG. 4A;

FIG. 5A is a circuit diagram of a delay circuit in accordance with a fourth embodiment of the present invention;

FIG. 5B is a graph illustrating variation of an effective resistance between a node A and a node B when a voltage level of a power supply voltage changes in the delay circuit of FIG. 5A; and

FIG. 5C is a graph illustrating variation of a delay time when a voltage level of a power supply voltage changes in the conventional delay circuit of FIG. 1C and the delay circuit of FIG. 5A.

### DETAILED DESCRIPTION OF THE INVENTION

A delay circuit in accordance with exemplary embodiments of the present invention will be described in detail with reference to the accompanying drawings.

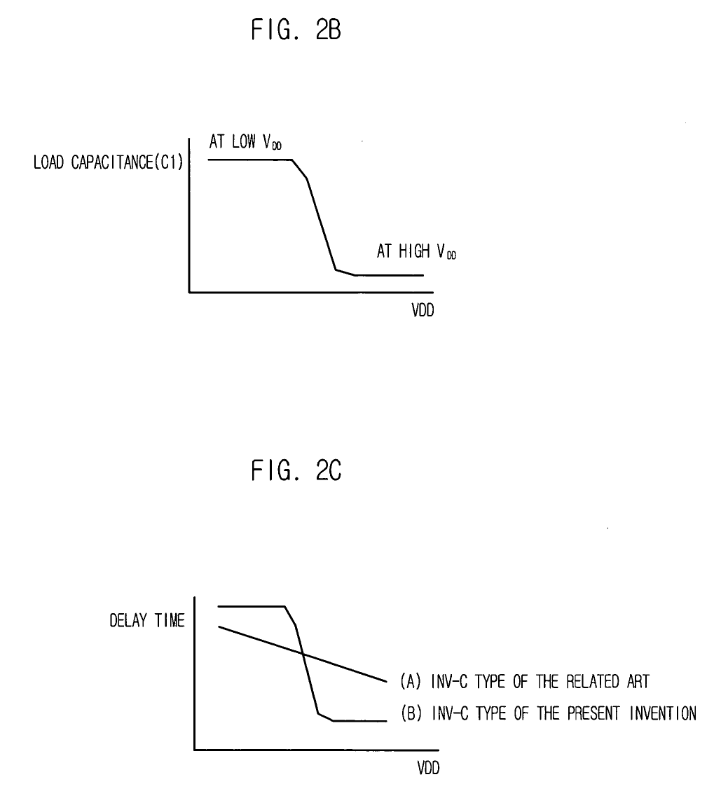

FIG. 2A is a circuit diagram of a delay circuit in accordance with a first embodiment of the present invention.

The delay circuit 100A includes first and second inverters INV1 and INV2, a capacitor C1, a switching unit 110, and a power supply voltage detector 150. The capacitor C1 has one terminal connected to a node A of a delay line IN-OUT, and the switching unit 110 is connected between the other terminal of the capacitor C1 and a ground terminal V_{SS}. The power supply voltage detector 150 detects whether a power supply voltage V_{DD} is higher or lower than a predetermined threshold voltage, and controls on/off operation of the switching unit 110. The threshold voltage is a preset voltage and can be changed by a designer.

The power supply voltage detector 150 turns off the switching unit 110 when the power supply voltage V_{DD} is higher than the threshold voltage, and turns on the switching unit 110 when the power supply voltage V_{DD} is lower than the threshold voltage.

The switching unit 110 includes a first NMOS transistor N1 having a gate receiving an output signal of the power supply voltage detector 150 and a drain-source path connected between the other terminal of the capacitor C1 and the ground terminal V_{SS}. Therefore, the switching unit 110 controls the connection between the other terminal of the capacitor C1 and the ground terminal V_{SS} in response to the output signal of the power supply voltage detector 150.

The power supply voltage detector 150 includes a voltage divider 152, a second NMOS transistor N2, and a PMOS transistor P1. The voltage divider 152 includes first and second resistor R1 and R2 which are connected in series between the power supply terminal V_{DD} and the ground terminal V_{SS} and generates a divided voltage DIVIDE_V at a node C. The second NMOS transistor N2 has a gate receiving the divided voltage DIVIDE_V and a drain-source path connected between the gate of the first NMOS transistor N1 at a node B and the ground terminal V_{SS}. The PMOS transistor P1 has a gate receiving the ground voltage V_{SS} and a source-drain path connected between the power supply terminal V_{DD} and the gate of the first NMOS transistor N1 at the node B.

FIG. 2B is a graph illustrating variation of the load capacitance looking into the node A when a voltage level of the power supply voltage changes in the delay circuit of FIG. 2A.

Because the delay circuit of FIG. 2A is implemented with first and second inverters INV1 and INV2 and the capacitor C1, it is an improved capacitor type delay circuit. An operation of the delay circuit of FIG. 2A will be described below with reference to FIG. 2B.

The voltage level of the power supply voltage V_{DD} is divided into a high operating voltage (high V_{DD}) higher than the predetermined threshold voltage and a low operating voltage (low V_{DD}) lower than the predetermined threshold voltage.

At the lower operating voltage, the divided voltage DIVIDE_V of the voltage divider 152 at the node C is lower than a threshold voltage (Vₜ) of the second NMOS transistor N2. Thus, the second NMOS transistor N2 is turned off so that the ground voltage V_{SS} is not transferred to the node B. On the other hand, the power supply voltage V_{DD} is transferred to the node B by the PMOS transistor P1 that is always turned on by the ground voltage V_{SS}. The first NMOS transistor N1 of the switching unit 110 is turned on by the voltage level of the node B, and the ground voltage V_{SS} is transferred to the capacitor C1. That is, a delay time required to charge and discharge the capacitor C1 by a voltage difference between both terminals of the capacitor C1 occurs so that the delay line IN-OUT maintains a high delay time state.

As the voltage level of the power supply voltage V_{DD} increases and approaches a voltage level higher than the threshold voltage, the divided voltage DIVIDE_V at the node C becomes higher than the threshold voltage (Vₜ) of the second NMOS transistor N2. At this point, the second NMOS transistor N2 is turned on and begins to transfer the ground voltage V_{SS} to the node B. As the voltage level of the power supply voltage V_{DD} continuously increases and the current drivability of the second NMOS transistor N2 exceeds that of the PMOS transistor P1, the voltage level of the node B is rapidly lowered. When the voltage level of the node B becomes lower than the threshold voltage (Vₜ) of the first NMOS transistor N1 of the switching unit 110, the first NMOS transistor N1 is turned off and the voltage level of the other terminal of the capacitor C connected to the ground terminal V_{SS} becomes a floating state. That is, the voltage difference between both terminals of the capacitor C disappears and the charge and discharge of the capacitor C does not occur. Consequently, the delay line IN-OUT maintains a low delay time state.

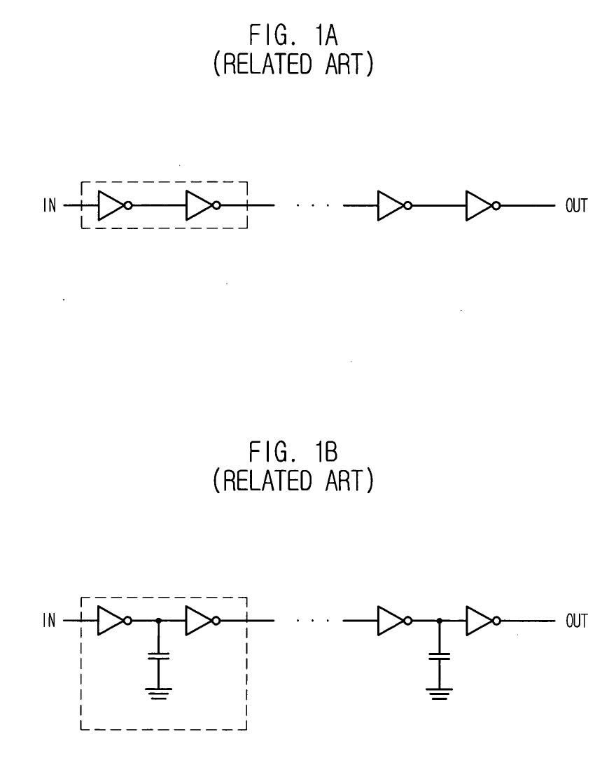

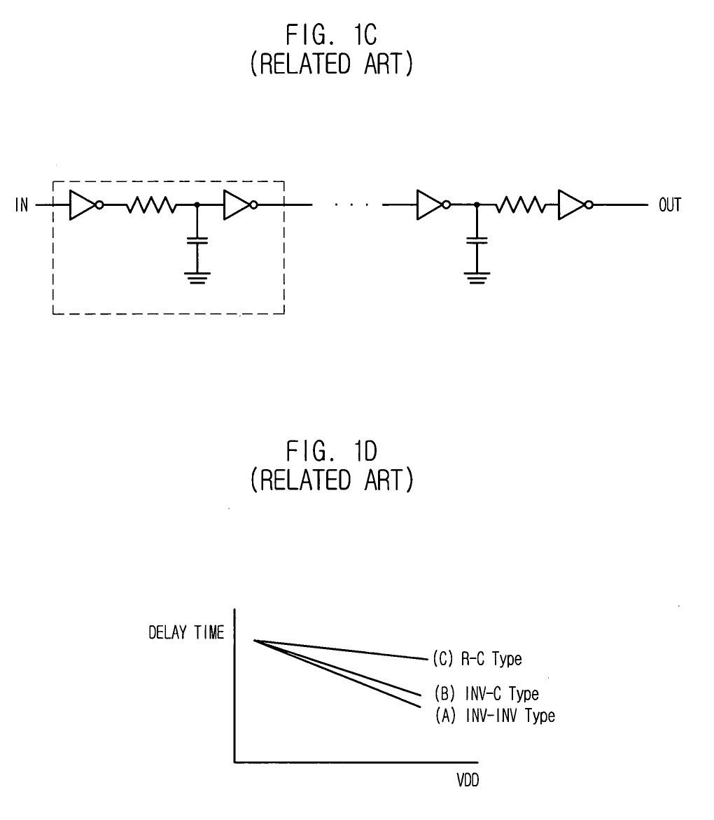

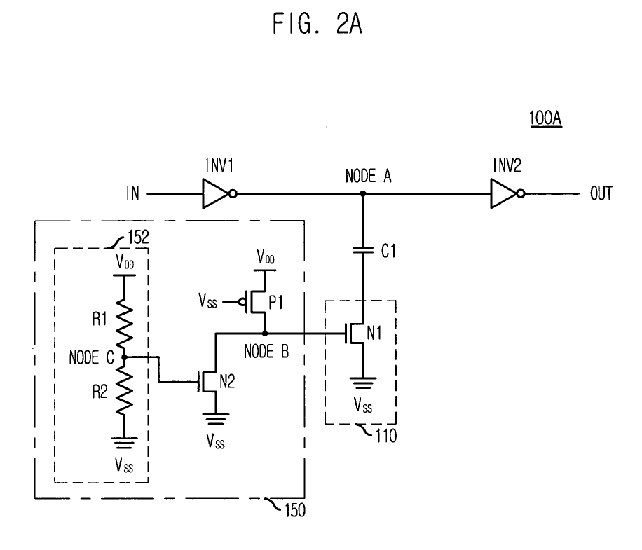

FIG. 2C is a graph illustrating variation of the delay time when the voltage level of the power supply voltage V_{DD} changes in the delay circuit of FIG. 1B and the delay circuit of FIG. 2A.

In the conventional capacitor type delay circuit of FIG. 1B, the delay time according to the change of the power supply voltage V_{DD} changes linearly without great variation. On the other hand, in the capacitor type delay circuit of FIG. 2A in accordance with the first embodiment of the present invention, the delay time according to the change of the power supply voltage V_{DD} changes rapidly with respect to the voltage level of the threshold voltage.

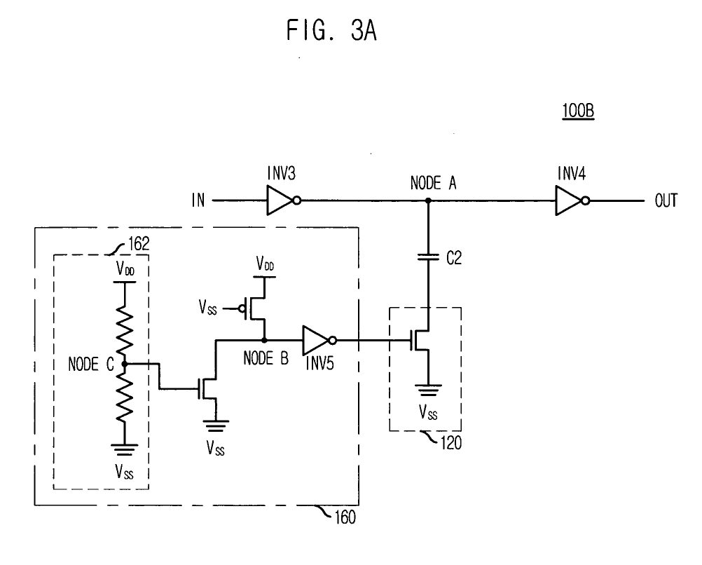

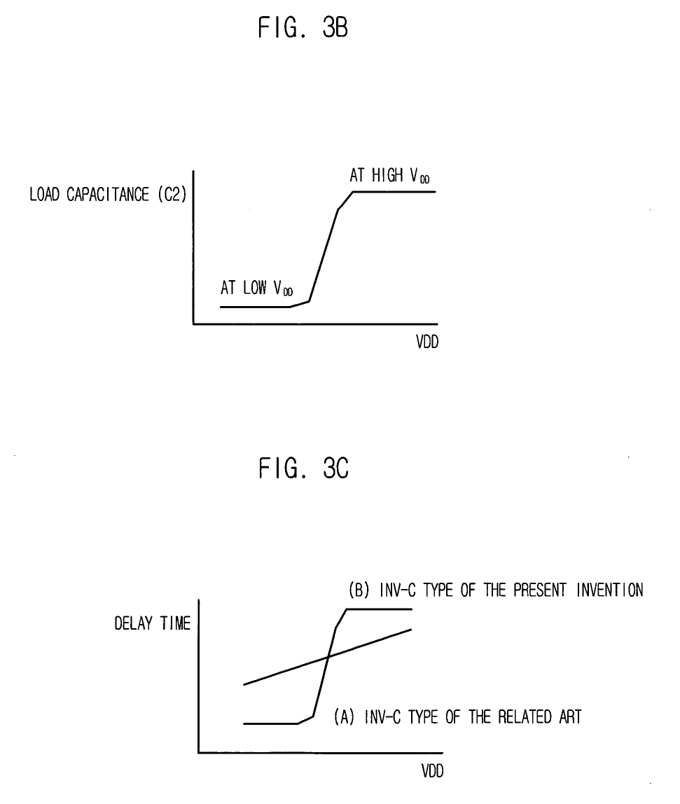

FIG. 3A is a circuit diagram of a delay circuit in accordance with a second embodiment of the present invention. The delay circuit 100B includes first and second inverters INV3 and INV4, a capacitor C2, a switching unit 120, and a power supply voltage detector 160. The delay circuit 100B further includes a third inverter INV5 in comparison with the delay circuit 100A.

The third inverter INV5 is connected between the power supply voltage detector 160 and the switching unit 120. Unlike the delay circuit of FIG. 2A, the delay circuit of FIG. 3A turns off the switching unit 120 when the power supply voltage V_{DD} is lower than the threshold voltage, and turns on the switching unit 120 when the power supply voltage V_{DD} is higher than the threshold voltage.

Consequently, the capacitor does not act as the load in the delay line IN-OUT when the power supply voltage V_{DD} is lower than the threshold voltage. On the other hand, the capacitor acts as the load in the delay line IN-OUT when the power supply voltage V_{DD} is higher than the threshold voltage.

FIG. 3B is a graph illustrating variation of the load capacitance looking into the node A when the voltage level of the power supply voltage changes in the delay circuit of FIG. 3A.

It can be seen from FIG. 3B that the graph of the variation of the delay time according to the change of the power supply voltage in the delay circuit of FIG. 3A is opposite to that in the delay circuit of FIG. 2A.

FIG. 3C is a graph illustrating variation of the delay time when the voltage level of the power supply voltage changes in the conventional delay circuit of FIG. 1B and the delay circuit of FIG. 3A.

In the conventional capacitor type delay circuit of FIG. 1B, the delay time according to the change of the power supply voltage V_{DD} changes linearly without great variation. On the other hand, in the capacitor type delay circuit of FIG. 3A in accordance with the second embodiment of the present invention, the delay time according to the change of the power supply voltage V_{DD} changes greatly with respect to the voltage level of the threshold voltage.

As described above, the capacitor type delay circuit in accordance with the present invention can vary the delay time greatly with respect to the change of the power supply voltage V_{DD} because it changes the capacitance of the capacitor in response to the change of the power supply voltage V_{DD}. That is, because the delay time at the high operating voltage and the delay time at the low operating voltage change greatly. Thus, the delay time can be independently controlled or adjusted at the high operating voltage and the low operating voltage.

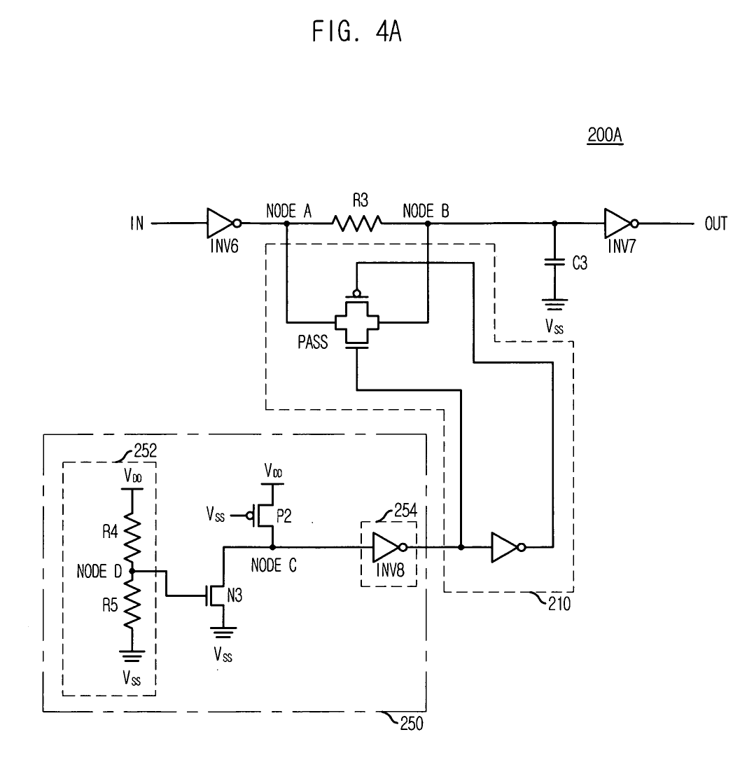

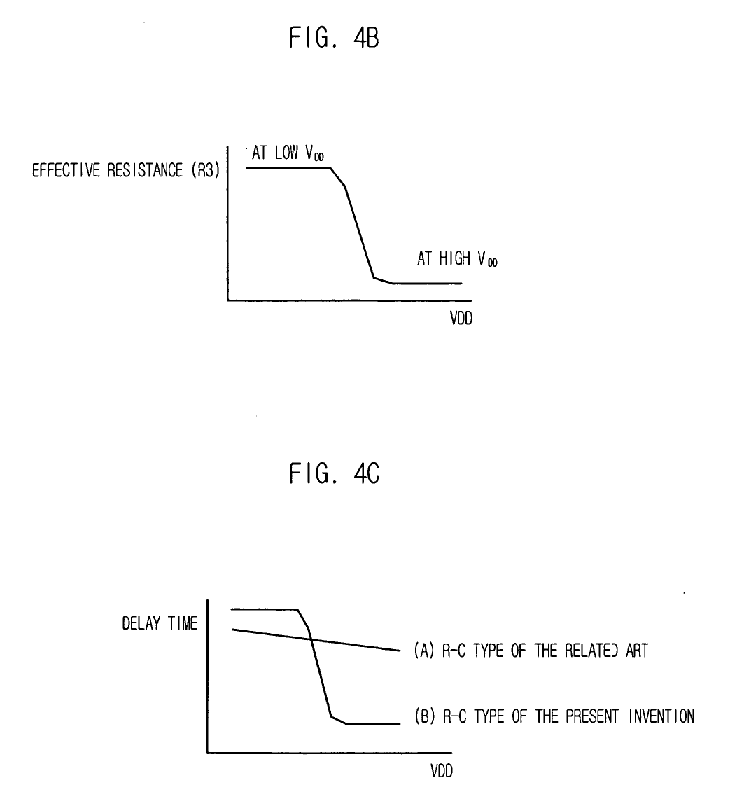

FIG. 4A is a circuit diagram of a delay circuit in accordance with a third embodiment of the present invention.

The delay circuit 200A includes first and second inverters INV6 and INV7, a capacitor C3, a first resistor R3, a switching unit 210, and a power supply voltage detector 250. The first resistor R3 is connected between an output terminal of the first inverter INV6 and an input terminal of the second inverter INV7. The first inverter INV6 and the second inverter INV7 constitute a delay line IN-OUT. The switching unit 210 is connected in parallel to the first resistor R3 between the output terminal of the first inverter INV6 and the input terminal of the second inverter INV7. The power supply voltage detector 250 detects whether a power supply voltage V_{DD} is higher or lower than a desired threshold voltage, and controls on/off operation of the switching unit 210.

The power supply voltage unit 250 turns on the switching unit 210 when the power supply voltage V_{DD} is higher than the threshold voltage, and turns off the switching unit 210 when the power supply voltage V_{DD} is lower than the threshold voltage.

The switching unit 210 includes a transfer gate PASS that is enabled or disabled in response to an output signal of the power supply voltage detector 250, and determines whether a current flowing between the output terminal of the first inverter INV6 and the input terminal of the second inverter INV7 passes through the enabled transfer gate PASS or the first resistor R3.

The power supply voltage detector 250 includes a voltage divider 252, an NMOS transistor N3, a PMOS transistor P2, and a driver 254. The voltage divider 252 includes second and third resistors R4 and R5 which are connected in series between the power supply terminal V_{DD} and the ground terminal V_{SS}, and generates a divided voltage DIVIDE_V at a node D. The NMOS transistor N3 has a gate receiving the divided voltage DIVIDE_V and a drain-source path connected between a node C and the ground terminal V_{SS}. The PMOS transistor P2 has a gate receiving the ground voltage V_{SS} and a source-drain path connected between the power supply terminal V_{DD} and the node C. The driver 254 includes a third inverter INV8 to control the transfer gate PASS in response to a signal applied to the node C.

FIG. 4B is a graph illustrating variation of an effective resistance between the node A and the node B when a voltage level of the power supply voltage changes in the delay circuit of FIG. 4A.

Because the delay circuit of FIG. 4A is implemented using the inverters and the resistor, it is an improved R-C type delay circuit. An operation of the delay circuit of FIG. 4A will be described below with reference to FIG. 4B.

The voltage level of the power supply voltage V_{DD} is divided into a high operating voltage higher than the desired threshold voltage and a low operating voltage lower than the desired threshold voltage.

The divided voltage DIVIDE_V of the voltage divider 252 at the node D is lower than a threshold voltage (Vₜ) of the NMOS transistor N3 at the lower operating voltage. Thus, the NMOS transistor N3 is turned off so that the ground voltage V_{SS} is not transferred to the node C. Therefore, the power supply voltage V_{DD} is transferred to the node C by the PMOS transistor P2 that is always turned on by the ground voltage V_{SS}, and the transfer gate PASS is disabled by the logic level of the output signal of the driver 254, which is determined as a logic low level by the voltage level of the node C. That is, a delay time occurs when a current flowing between the output terminal of the first inverter INV6 and the input terminal of the second inverter INV7 passes through the first resistor R3, so that the delay line IN-OUT maintains a high delay time state.

As the voltage level of the power supply voltage V_{DD} increases and approaches a voltage level higher than the threshold voltage, the divided voltage DIVIDE_V of the voltage divider 252 becomes higher than the threshold voltage (Vₜ) of the NMOS transistor N3. At this point, the NMOS transistor N3 is turned on to connect the ground voltage V_{SS} and the node C and thus begins to discharge the voltage applied to the node C. Then, as the voltage level of the power supply voltage V_{DD} continuously increases and the current drivability of the NMOS transistor N3 exceeds that of the PMOS transistor P2, the voltage level of the node C is rapidly lowered. When the voltage level of the node C becomes a logic high level, the transfer gate PASS is enabled. That is, the current flowing between the output terminal of the first inverter INV6 and the input terminal of the second inverter INV7 passes through the enabled transfer gate PASS having almost no resistive component and the delay line IN-OUT maintains a low delay time state.

FIG. 4C is a graph illustrating variation of the delay time when the voltage level of the power supply voltage changes in the conventional delay circuit of FIG. 1C and the delay circuit of FIG. 4A.

In the conventional R-C type delay circuit of FIG. 1C, the delay time according to the change of the power supply voltage V_{DD} changes linearly without great variation. On the other hand, in the R-C type delay circuit of FIG. 4A in accordance with the third embodiment of the present invention, the delay time according to the change of the power supply voltage V_{DD} changes greatly with respect to the voltage level of the threshold voltage.

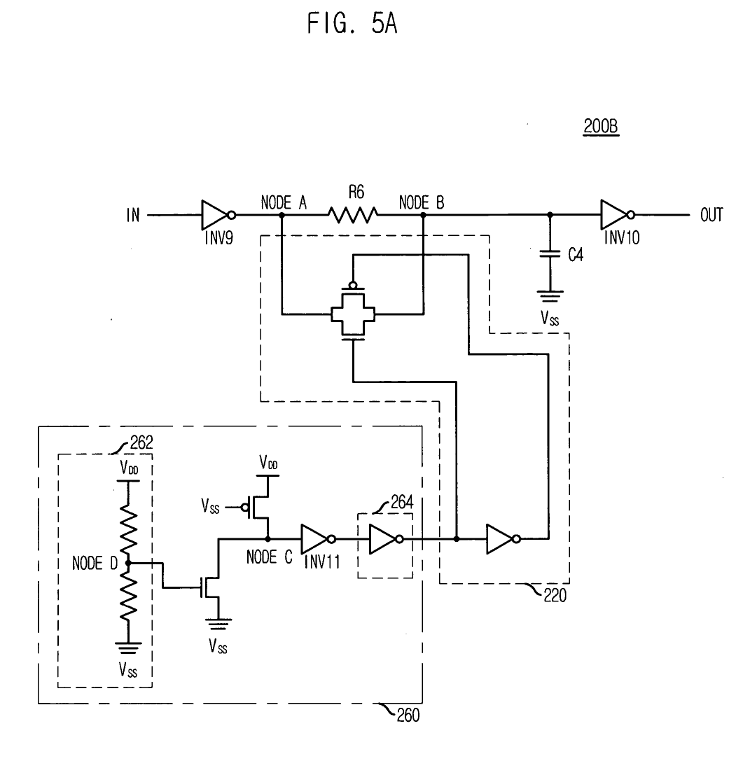

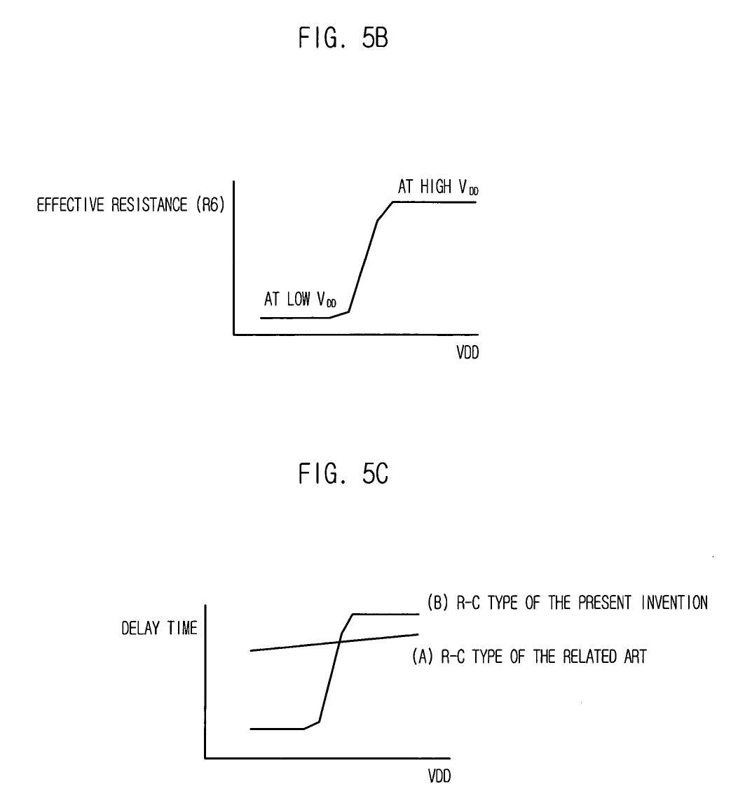

FIG. 5A is a circuit diagram of a delay circuit in accordance with a fourth embodiment of the present invention.

The delay circuit 200B includes first and second inverters INV9 and INV10, a capacitor C4, a resistor R6, a switching unit 220, and a power supply voltage detector 260. The delay circuit 200B further includes a third inverter INV11 in comparison with the delay circuit 200A. The third inverter INV11 is connected between the node C and the driver 264 in the power supply voltage detector 260. Unlike the delay circuit of FIG. 4A, the delay circuit of FIG. 5A turns on the switching unit 220 when the power supply voltage V_{DD} is lower than the threshold voltage, and turns off the switching unit 220 when the power supply voltage V_{DD} is higher than the threshold voltage.

Consequently, when the power supply voltage V_{DD} is lower than the threshold voltage, the resistor R6 does not act as the load in the delay line IN-OUT. On the other hand, the resistor R6 acts as the load in the delay line IN-OUT when the power supply voltage V_{DD} is higher than the threshold voltage.

FIG. 5B is a graph illustrating variation of an effective resistance between the node A and the node B when the voltage level of the power supply voltage changes in the delay circuit of FIG. 5A.

It can be see from FIG. 5B that the graph of the variation of the delay time according to the change of the power supply voltage in the delay circuit of FIG. 5A is opposite to that in the delay circuit of FIG. 4A.

FIG. 5C is a graph illustrating variation of the delay time when the voltage level of the power supply voltage changes in the conventional delay circuit of FIG. 1C and the delay circuit of FIG. 5A.

In the conventional R-C type delay circuit of FIG. 1C, the delay time according to the change of the power supply voltage V_{DD} changes linearly without great variation. On the other hand, in the R-C type delay circuit of FIG. 5A in accordance with the fourth embodiment of the present invention, the delay time according to the change of the power supply voltage V_{DD} changes greatly with respect to the voltage level of the threshold voltage.

As described above, the R-C type delay circuit in accordance with the present invention selects one of a plurality of paths having different resistors according to the change of the power supply voltage V_{DD}, and makes a current passing through the delay line IN-OUT flow through the selected path. Therefore, the time taken to pass through the delay line IN-OUT can be varied greatly. That is, because the delay time changes greatly at the high operating voltage and the low operating voltage, the delay time can be independently controlled or adjusted.

In addition, the method described in the first and second embodiments of the present invention can also be applied to the R-C type delay circuits in accordance with the third and fourth embodiments of the present invention. That is, the time taken to pass through the delay line IN-OUT can be changed greatly by changing an amount of electric charges applied to the capacitor according to the change of the power supply voltage.

As described above, by changing the capacitance of the capacitor connected in parallel to the delay line IN-OUT according to the change of the power supply voltage, or by making a current flow through one selected from a plurality of paths having different resistors between the input and the output of the delay line IN-OUT, the present invention can independently control or adjust the delay time by greatly changing the time taken to pass through the delay line IN-OUT according to the change of the power supply voltage.

The present application contains subject matter related to Korean patent application Nos. 2005-90881 & 2006-43561, filed in the Korean Intellectual Property Office on Sep. 29, 2005 & May 15, 2006, the entire contents of which is incorporated herein by reference.

While the present invention has been described with respect to certain preferred embodiments, it will be apparent to those skilled in the art that various changes and modifications may be made without departing from the scope of the invention as defined in the following claims.

What is claimed is:

1. A delay circuit, comprising:
a plurality of inverters, connected in series, for delaying an input signal;
a power supply voltage detector for detecting whether a power supply voltage is higher or lower than a predetermined threshold voltage; and
a load connected to a node between the inverters and having different impedances according to levels of the power supply voltage in response to the detected result of the power supply voltage detector.

2. A delay circuit, comprising:
a capacitor having one terminal connected to a node of a delay line;
a switching unit connected between the other terminal of the capacitor and a ground terminal; and
a power supply voltage detector for controlling the switching unit by detecting whether a power supply voltage is higher or lower than a predetermined threshold voltage.

3. The delay circuit of claim 2, wherein the power supply voltage detector turns off the switching unit when the power supply voltage is higher than the threshold voltage, and turns on the switching unit when the power supply voltage is lower than the threshold voltage.

4. The delay circuit of claim 3, wherein the switching unit includes a first NMOS transistor having a gate receiving an output signal of the power supply voltage detector and a drain-source path connected between the other terminal of the capacitor and the ground terminal.

5. The delay circuit of claim 4, wherein the power supply voltage detector includes:
a voltage divider connected in series between the power supply terminal and the ground terminal to generate a divided voltage;
a second NMOS transistor having a gate receiving the divided voltage and a drain-source path connected between the gate of the first NMOS transistor and the ground terminal; and
a PMOS transistor having a gate receiving the ground voltage and a source-drain path connected between the gate of the first NMOS transistor and the power supply terminal.

6. The delay circuit of claim 5, wherein the voltage divider includes a first resistor and a second resistor connected in series between the power supply terminal and the ground terminal and outputs the divided voltage at a common node of the first resistor and the second resistor.

7. The delay circuit of claim 2, wherein the power supply voltage detector turns off the switching unit when the power supply voltage is lower than the threshold voltage, and turns on the switching unit when the power supply voltage is higher than the threshold voltage.

8. The delay circuit of claim 7, wherein the switching unit includes a first NMOS transistor having a gate receiving an output signal of the power supply voltage detector and a drain-source path connected between the other terminal of the capacitor and the ground terminal.

9. The delay circuit of claim 8, wherein the power supply voltage detector includes:
a voltage divider connected in series between the power supply terminal and the ground terminal to generate a divided voltage;
a second NMOS transistor having a gate receiving the divided voltage and a drain-source path connected between a first node and the ground terminal;
a PMOS transistor having a gate receiving the ground voltage and a source-drain path connected between the power supply terminal and the first node; and
an inverter having an input terminal connected to the first node and an output terminal connected to the gate of the first NMOS transistor.

10. The delay circuit of claim 9, wherein the voltage divider includes first and second resistors connected in series between the power supply terminal and the ground terminal and outputs the divided voltage at a common node of the first resistor and the second resistor.

11. A delay circuit, comprising:
a resistor connected between an output terminal of a first inverter and an input terminal of a second inverter, the first and second inverters forming a delay line;
a switching unit connected in parallel to the resistor between the output terminal of the first inverter and the input terminal of the second inverter; and
a power supply voltage detector for controlling the switching unit by detecting whether a power supply voltage is higher or lower than a predetermined threshold voltage.

12. The delay circuit of claim 11, wherein the power supply voltage detector turns on the switching unit when the power supply voltage is higher than the threshold voltage, and turns off the switching unit when the power supply voltage is lower than the threshold voltage.

13. The delay circuit of claim 12, wherein the switching unit is a transfer gate connected between the output terminal of the first inverter and the input terminal of the second inverter.

14. The delay circuit of claim 13, wherein the power supply voltage detector includes:
a voltage divider connected in series between a power supply terminal and a ground terminal to generate a divided voltage;
an NMOS transistor having a gate receiving the divided voltage and a drain-source path connected between a first node and the ground terminal;
a PMOS transistor having a gate receiving the ground voltage and a source-drain path connected between the power supply terminal and the first node; and
a driver for controlling the transfer gate in response to a signal applied to the first node.

15. The delay circuit of claim 14, wherein the voltage divider includes first and second resistors connected in series between the power supply terminal and the ground terminal, and outputs the divided voltage at a common node of the first resistor and the second resistor.

16. The delay circuit of claim 11, wherein the power supply voltage detector turns on the switching unit when the power supply voltage is lower than the threshold voltage, and turns off the switching unit when the power supply voltage is higher than the threshold voltage.

17. The delay circuit of claim 16, wherein the switching unit is a transfer gate connected between the output terminal of the first inverter and the input terminal of the second inverter.

18. The delay circuit of claim 17, wherein the power supply voltage detector includes:
a voltage divider connected in series between the power supply terminal and the ground terminal to generate the divided voltage;
an NMOS transistor having a gate receiving the divided voltage and a drain-source path connected between a first node and the ground voltage;
a PMOS transistor having a gate receiving the ground voltage and a source-drain path connected between the power supply terminal and the first node;
a third inverter for inverting a signal applied to the first node; and
a driver for controlling the transfer gate in response to an output signal of the third inverter.

19. The delay circuit of claim 18, wherein the voltage divider includes first and second resistors connected in series between the power supply terminal and the ground terminal, and outputs the divided voltage at a common node of the first resistor and the second resistor.
